(19) United States
(12) Patent Application Publication
(10) Pub. No.: US 2025/0212514 A1
(43) Pub. Date: Jun. 26, 2025

(54) ARRAY SUBSTRATE, METHOD OF MANUFACTURING THEREOF, AND DISPLAY PANEL

(71) Applicants: Zhengjuan SUN, Guangzhou (CN); Zifang SU, Guangzhou (CN); Ronglei DAI, Guangzhou (CN)

(72) Inventors: Zhengjuan SUN, Guangzhou (CN); Zifang SU, Guangzhou (CN); Ronglei DAI, Guangzhou (CN)

(21) Appl. No.: 18/395,331

(22) Filed: Dec. 22, 2023

(51) Int. Cl. H01L 27/12; G02F 1/1362

(52) U.S. Cl. CPC H10D 86/60; H10D 86/0251; H10D 86/451; G02F 1/1362; H10D 86/441

(57) ABSTRACT

An array substrate includes a substrate, a first conductor layer, a protective layer, a gate insulating layer, an active layer, and a second conductor layer. The first conductor layer includes a gate in a thin film transistor area. The protective layer is disposed on the first conductor layer and includes a gate protecting unit on the gate. The gate insulating layer is disposed on the gate protecting unit. The active layer is disposed on the gate insulating layer and in a thin film transistor area. The second conductor layer is disposed on a side of the active layer away from the substrate and includes a source and a drain at intervals in the thin film transistor area.

### CROSS-REFERENCE TO RELATED APPLICATION

This application claims priority to and the benefit of Chinese Patent Application No. 202311207086.0, filed on Sep. 18, 2023, the disclosure of which is incorporated herein by reference in its entirety.

### TECHNICAL FIELD

The present disclosure relates to display technologies, and in particular, to an array substrate, a method of manufacturing thereof, and a display panel.

### BACKGROUND

Liquid crystal display devices are currently the most widely used flat panel displays, which may provide color screens with high resolution for various electronic devices, such as mobile phones, personal digital assistants (PDA), digital cameras, and computers. The liquid crystal display devices based on fringe field switching (FFS) mode are popular with among users for their wide viewing angle and high aperture ratio.

In the liquid crystal display devices based on the FFS mode, a thickness of a dielectric layer (a gate insulating layer and a passivation layer) between a pixel electrode and a common electrode is larger, resulting in a smaller storage capacitance of a pixel and a larger voltage fluctuation when the pixel electrode and the common electrode are coupled, flicker and abnormal display of special images, such as crosstalk, are prone to occur. As a result, the liquid crystal display devices cannot be mass-produced, VOP is higher, and power consumption is increased. VOP is a parameter of liquid crystals, which is the turn-on voltage (a cross voltage at maximum deflection).

At present, in order to reduce the thickness of the dielectric layer between the pixel electrode and the common electrode, generally, the gate insulating layer is etched before ashing a photoresist layer disposed on a source-drain layer to thin the gate insulating layer. However, an etching rate of the gate insulating layer is difficult to control, so that a uniformity of the thickness of the gate insulating layer is difficult to be ensured. If the gate insulating layer between the pixel electrode and the common electrode is completely removed before ashing the photoresist layer on the source-drain layer, the gate is easily exposed. When the source-drain layer is etched later, the exposed gate is easily etched, resulting in a failure of an array substrate.

### SUMMARY

The present disclosure provides an array substrate, a method of manufacturing thereof, and a display panel, to solve a problem of taste degradation caused by poor thickness uniformity of a gate insulating layer and reduce a failure probability of thin film transistors.

To solve the problem above mentioned, the present disclosure provides an array substrate including a thin film transistor area and a pixel opening area, and further includes a substrate, a first conductor layer, a protective layer, a gate insulating layer, an active layer, an active layer, and a second conductor layer. The first conductor layer is disposed on the substrate and includes a gate in the thin film transistor area. The protective layer is disposed on the first conductor layer and includes a gate protecting unit on the gate. The gate insulating layer is disposed on the gate protecting unit. The active layer is disposed on the gate insulating layer and in the thin film transistor area. The second conductor layer is disposed on a side of the active layer away from the substrate and includes a source and a drain at intervals in the thin film transistor area.

To solve the problem above mentioned, the present disclosure further provides a method of manufacturing the array substrate including: forming a first sub-conductor material layer on a substrate, and patterning the first sub-conductor material layer to form a first conductor layer comprising a gate in a thin film transistor area of the array substrate; forming a protective material layer on the first conductor layer, and patterning the protective material layer to form a protective layer comprising a gate protecting unit on the gate; forming a gate insulating material layer on the protective layer; forming a semiconductor layer on the gate insulating material layer; forming a second conductor material layer on a side of the semiconductor layer away from the substrate; forming a photoresist layer on the second conductor material layer; patterning the second conductor material layer and the active layer with the photoresist layer as a mask to form an active layer in the thin film transistor area; removing the gate insulating material layer not covered by the active layer to form a gate insulating layer, and removing a part of the photoresist layer to expose the second conductor material layer; and etching the second conductor material layer not covered by the photoresist layer to form a second conductor layer including a source and a drain at intervals.

To solve the problem above mentioned, the present disclosure further provides a display panel including the array substrate above mentioned.

Beneficial effects of the present disclosure are: in the present disclosure, the protective layer is disposed on a side of the first conductor layer away from the substrate, and the gate protecting unit of the protective layer is used to protect the gate of the first conductor layer, so as to prevent the gate from being etched when the second conductor layer is etched, and avoid a failure of the array substrate. The gate insulating layer between the pixel electrode and the common electrode may be completely removed, so that capacitance is improved, VOP is reduced, power consumption is reduced, flickers and abnormal display of special images are avoided, the thickness uniformity of the dielectric layer between the pixel electrode and the common electrode is ensured, and a taste of the display panel is improved.

### BRIEF DESCRIPTION OF THE DRAWINGS

To describe technical solutions of embodiments of the present disclosure more clearly, the following briefly introduces accompanying drawings used in a description of the embodiments of the present disclosure. Apparently, the accompanying drawings only some exemplary embodiments of the present disclosure, and persons skilled in the art may derive other drawings from the drawings without making creative efforts.

FIG. 1 is a schematic structural diagram of a display panel according to an embodiment of the present disclosure.

FIG. 2 is a schematic structural diagram of the display panel after a first etching of a second conductor material layer.

FIG. 3 is a schematic structural diagram of the display panel after an etching of an ohmic contact unit material layer and an amorphous silicon material layer on the basis of FIG. 2.

FIG. 4 is a schematic structural diagram of the display panel after an etching of a gate insulating material layer on the basis of FIG. 3.

FIG. 5 is a schematic structural diagram of the display panel after a second etching of the second conductor material layer on the basis of FIG. 4.

FIG. 6 is a schematic structural diagram of the display panel after a second etching of the ohmic contact unit material layer on the basis of FIG. 5.

### DETAILED DESCRIPTION

Embodiments of the present disclosure will be described in detail hereinafter with reference to the accompanying drawings, to fully introduce technical content of the present disclosure to a person skilled in the art, to testify that the present disclosure can be implemented as examples, to better clarify technical content of the present disclosure, to assist the person skilled in the art in easier understanding how to implement the present disclosure. However, the present disclosure can be embodied in many different forms, the scope of the present disclosure is not limited to the embodiments mentioned in the text, and the description of the embodiments in the following text is not used to limit the scope of the present disclosure.

The following description of every embodiment with reference to the accompanying drawings is used to exemplify a specific embodiment which may be carried out in the present disclosure. Directional terms mentioned in the present disclosure, such as “top”, “bottom”, “front”, “back”, “left”, “right”, “inside”, “outside”, “side” etc., are only used with reference to orientations of the accompanying drawings. Therefore, the used directional terms are intended to illustrate, but not to limit, the present disclosure.

In the accompanying drawings, elements with identical structure are marked with the same reference numerals, and components with similar structures or functions are marked with similar reference numerals. In addition, for convenient understanding and description, the dimension and thickness of each of the elements in the accompanying drawings are arbitrarily shown, and the present disclosure does not define the dimension and thickness of each of the elements

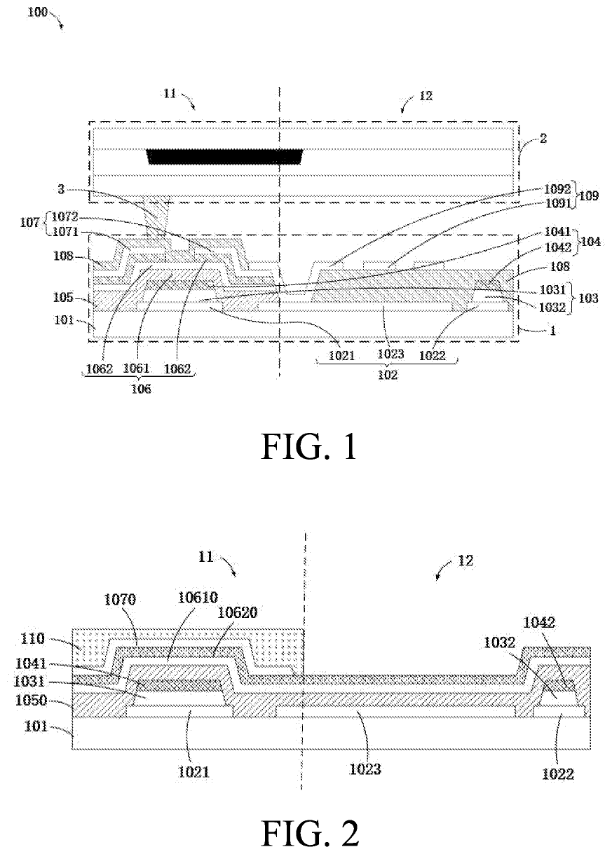

Referring to FIG. 1, the present disclosure provides an array substrate 1. The array substrate 1 includes a thin film transistor area 11 and a pixel opening area 12.

The array substrate 1 includes a substrate 101, a first conductor layer, a protective layer 104, a gate insulating layer 105, an active layer 106, an active layer 106, a second conductor layer 107, a passivation layer 108, and a third conductor layer 109.

The substrate 101 is disposed in the thin film transistor area 11 and the pixel opening area 12. A material of the substrate 101 includes glass, polyimide, polycarbonate, polyethylene glycol terephthalate, polyethylene naphthalate two formic acid glycol ester, and the like. In this embodiment, the material of the substrate 101 is glass.

The first conductor layer is disposed on the substrate 101. Specifically, the first conductor layer includes a first sub conductor layer 102 disposed on the substrate 101 and a second sub conductor layer 103 disposed on the first sub conductor layer 102.

A material of the first sub conductor layer 102 may be a transparent electrode such as indium tin oxide (ITO). The first sub conductor layer is used to be one of a pixel electrode and a common electrode. In this embodiment, the first sub conductor layer is used to be the pixel electrode. Specifically, the first sub conductor layer 102 includes a first conductive unit 1021, a second conductive unit 1022, and the pixel electrode 1023 at intervals, and the pixel electrode 1023 is disposed between the first conductive unit 1021 and the second conductive unit 1022. The first conductive unit 1021 is disposed in the thin film transistor area 11, the pixel electrode 1023 is disposed in the pixel opening area 12, and the second conductive unit 1022 is located on a side of the pixel electrode 1023 away from the first conductive unit 1021.

The second sub conductor layer 103 is disposed on a side of the first sub conductor layer 102 away from the substrate 101. The second sub conductor layer 103 may be a single-layer structure such as Mo, Al, Cu, Ti, or a multi-layer structure such as Mo/Al/Mo, Al/Mo, Mo/Cu, MoTi/Cu. A thickness of the second sub conductor layer 103 ranges from 500 Å to 10000 Å. In this embodiment, the thickness of the second sub conductor layer 103 is 1000 Å.

Specifically, the second sub conductor layer 103 includes a gate 1031 and a common wiring 1032 spaced apart from each other. The gate 1031 corresponds to the first conductive unit 1021 and is disposed in the thin film transistor area 11, and the common wiring 1032 corresponds to the second conductive unit 1022.

The protective layer 104 is disposed on a side of the first conductor layer away from the substrate 101. Specifically, the protective layer 104 is disposed on a side of the second sub conductor layer 103 away from the substrate 101. Specifically, the protective layer 104 includes a gate protecting unit 1041 covering the gate 1031 and a common wiring protecting unit 1042 covering the common wiring 1032. The gate protecting unit 1041 corresponds to the gate 1031 and is disposed in the thin film transistor area 11, and the common wiring protecting unit 1042 corresponds to the common wiring 1032.

An etching solution used for patterning the second conductive layer 107 cannot etch the protective layer 104. Specifically, a material of the protective layer 104 includes one or more of ITO, IGZO, and IZO. In this embodiment, the material of the protective layer is ITO. When the second conductor layer 107 is etched, the gate 1031 under the protective layer 104 cannot be etched.

A thickness of the protective layer 104 ranges from 500 Å to 1300 Å. In this embodiment, the thickness of the protective layer 104 is 900 Å.

In summary, in the present disclosure, the protective layer 104 is disposed on a side of the first conductor layer away from the substrate 101, and the gate protecting unit 1041 of the protective layer 104 is used to protect the gate 1031 of the first conductor layer, so as to prevent the gate 1031 from being etched when the second conductor layer 107 is etched, and avoid a failure of the array substrate 1. The gate insulating layer 105 between the pixel electrode 1023 and the common electrode 1091 may be completely removed, so that capacitance is improved, VOP is reduced, power consumption is reduced, flickers and abnormal display of special images are avoided, the thickness uniformity of the dielectric layer between the pixel electrode 1023 and the common electrode 1091 is ensured, and a taste of the display panel is improved.

The gate insulating layer 105 is disposed on a side of the protective layer 104 away from the substrate 101 and in the thin film transistor area 11, which is mainly used to prevent short circuits from occurring in contact between the active layer 106 and the gate 1031. The gate insulating layer 105 may be made of SiOx, SiNₓ, Al₂O₃, a combined structure of SiNₓ and SiOₓ, or a combined structure of SiOₓ, SiNx, and SiOx. In this embodiment, the gate insulating layer 105 may be made of SiO₂. A thickness of the gate insulating layer 105 ranges from 1000 Å is 3000 Å. In this embodiment, the thickness of the gate insulating layer is 2000 Å.

An orthographic projection of the gate insulating layer 105 on the substrate 101 is located outside an orthographic projection of the pixel opening area 12 on the substrate 101. In other words, the gate insulating layer 105 is not disposed in the pixel opening area 12, and further not disposed between the pixel electrode 1023 and the common electrode 1091, so that the capacitance is improved, the VOP is reduced, the power consumption is reduced, flickers and abnormal display of special images are avoided, the thickness uniformity of the dielectric layer between the pixel electrode 1023 and the common electrode 1091 is ensured, and a taste of the display panel is improved.

The active layer 106 is disposed on a side of the gate insulating layer 105 away from the substrate 101, corresponds to the gate 1031, and is disposed in the thin film transistor area 11. In this embodiment, the active layer 106 includes an amorphous silicon layer 1061 and two ohmic contact units 1062. The amorphous silicon layer 1061 is disposed on the side of the gate insulating layer 105 away from the substrate 101 and is disposed corresponding to the gate 1031. The two ohmic contact units 1062 are respectively disposed at both ends of the amorphous silicon layer 1061 and on a side of the amorphous silicon layer 1061 away from the substrate 101. The ohmic contact units 1062 may further reduce the contact resistance between the amorphous silicon layer 1061 and the second conductor layer 107 to improve current efficiency. In other embodiments, the material of the active layer 106 may further be a semiconductor material, such as a metal oxide.

The second conductor layer 107 is disposed on a side of the active layer 106 away from the substrate 101. The second conductor layer 107 includes a source 1071 and a drain 1072 spaced apart from each other and disposed in the thin film transistor area 11. The source 1071 and the drain 1072 are connected to the two ohmic contact units 1062 respectively.

The passivation layer 108 is disposed on a side of the second conductor layer 107 in the film transistor area 11 away from the substrate 101, and further disposed on a side of the pixel electrode 1023 in the pixel opening area 12 away from the substrate 101. A material of the passivation layer 108 includes one or more of SiO₂ and SiNₓ. In this embodiment, the material of the passivation layer 108 is SiO₂. A thickness of the passivation layer 108 ranges from 1000 Å to 5000 Å. In this embodiment, the thickness of the passivation layer 108 is 2000 Å.

The third conductor layer 109 is disposed on the passivation layer 108. In this embodiment, a material of the third conductor layer 109 is a transparent conductive material, such as ITO. The third conductor layer 109 includes another one of the pixel electrode and the common electrode. Since the first sub conductor layer 102 is used to be the pixel electrode 1023, in this embodiment, the third conductor layer 109 includes the common electrode 1091. Specifically, the third conductor layer 109 includes the common electrode 1091 corresponding to the pixel electrode 1023 and in the pixel opening area 12. In other embodiments, the first sub conductor layer may further be used to be the common electrode, and the third conductor layer may include the pixel electrode.

The third conductor layer 109 further includes a drain connecting part 1092 for electrically connecting the drain 1072 and the pixel electrode 1023. Specifically, the passivation layer 108 is provided with a drain contact hole exposing the first sub conductor layer 102, and a part of the third conductor layer 109 located in the drain contact hole and connected to the drain 1072 and pixel electrode 1023 is called the drain connection part 1092.

The present disclosure further provides a method of manufacturing the array substrate 1 including following steps:
step S1, forming a first sub conductor material layer on a substrate 101, and patterning the first sub-conductor material layer to form a first conductor layer including a gate 1031 in a thin film transistor area 11; step S2, forming a protective material layer on the first conductor layer, and patterning the protective material layer to form a protective layer 104 including a gate protecting unit 1041 on the gate 1031; step S3, forming a gate insulating material layer 1050 on the protective layer 104; step S4, forming a semiconductor layer 1060 on the gate insulating material layer 1050; step S5, forming a second conductor material layer 1070 on a side of the semiconductor layer 1060 away from the substrate 101; step S6, forming a photoresist layer 110 on the second conductor material layer 1070; step S7, patterning the second conductor material layer 1070 and the active layer 1060 with the photoresist layer 110 as a mask to form an active layer 106 in the thin film transistor area 11; step S8, removing the gate insulating material layer 1050 not covered by the active layer 106 to form a gate insulating layer 105, and removing a part of the photoresist layer 110 to expose the second conductor material layer 1070; and step S9, etching the second conductor material layer 1070 not covered by the photoresist layer 110 to form a second conductor layer 107 including a source 1071 and a drain 1072 at intervals; step S10, forming a passivation layer 108 on a side of the second conductor layer 107 away from the substrate 101, and patterning the passivation layer 108 to form a source contact hole exposing the first sub conductor layer 102; and step S11, forming a third conductor layer 109 on the passivation layer 108, and patterning the third conductor layer 109 to form another one of the pixel electrode and the common electrode and a drain connecting part connecting the drain 1072 to the first sub conductor layer 102.

In this embodiment, the third conductor layer 109 includes the common electrode 1091, and the third conductor layer 109 further includes the drain connecting art 1092 that connects the drain 1072 to the first sub conductor layer 102 through the drain contact hole.

Specifically, the steps S1-S2 include: forming a first sub-conductor material layer on the substrate 101; forming a second sub conductor material layer on the first sub conductor material layer; forming the protective material layer on the second sub conductor material layer; and patterning the protective material layer, the second sub conductor material layer, and the first sub-conductor material layer to form the protective layer 104, a second sub conductor layer 103, and a first sub conductor layer 102.

The first sub conductor layer 102 in the pixel opening area 12 serves as one of the pixel electrode and the common electrode. In this embodiment, the first sub conductor layer 102 in the pixel opening area 12 is used to be the pixel electrode. The first sub conductor layer 102 includes a first conductive unit 1021, the pixel electrode 1023, and a second conductive unit 1022 at intervals. The first conductive unit 1021 is located in the thin film transistor area 11, the pixel electrode 1023 is located in the pixel opening area 12, and the second conductive unit 1022 is located on a side of the pixel electrode 1023 away from the first conductive unit 1021. The first sub conductor layer 102 includes the gate 1031 and a common wiring 1032 spaced apart from the gate 1031. The protective layer 104 includes a gate protecting unit 1041 covering the gate 1031 and a common wiring protecting unit 1042 covering the common wiring 1032.

Referring to FIG. 2, the step S4 includes: forming an amorphous silicon material layer 10610 on a side of the gate insulating material layer 1050 away from the substrate, and forming an ohmic contact unit material layer 10620 on a side of the amorphous silicon material layer 10610 away from the substrate 101.

As shown in FIG. 2, the step S7 includes: etching the second conductor material layer 1070 for the first time with the photoresist layer 110 as a mask, the photoresist layer 110 being located in the thin film transistor area 11, and the second conductor material layer 1070 covered by the photoresist 110 being retained.

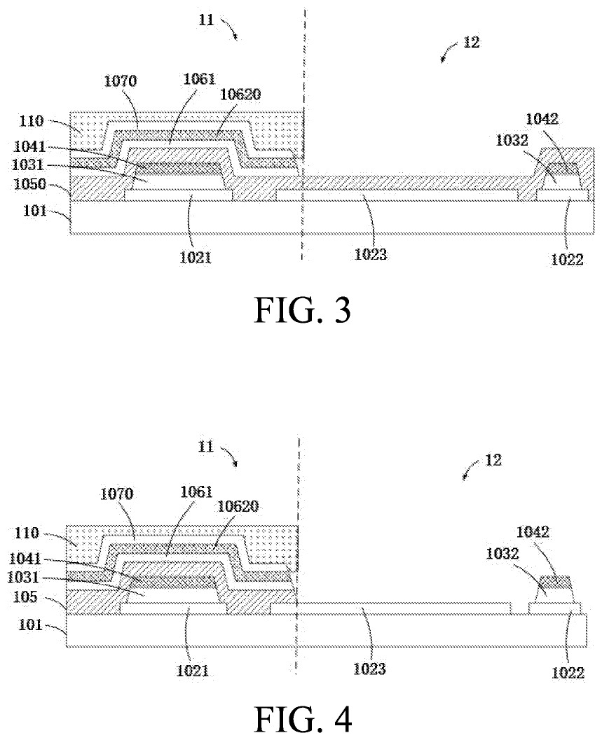

Referring to FIG. 3, the steps S7-S9 include: etching the semiconductor layer 1060 with the photoresist layer 110 as a mask to retain the semiconductor layer 1060 covered by the photoresist layer 110. Specifically, the ohmic contact unit material layer 10620 and the amorphous silicon material layer 10610 are etched by a dry etching process using the mask, the amorphous silicon material layer 10610 corresponding to the gate 1031 is retained to form the amorphous silicon layer 1061, and the ohmic contact unit material layer 10620 corresponding to the gate 1031 is retained.

Referring to FIG. 4, the steps S7-S9 further include: using a mask, etching the gate insulating material layer 1050 by using a dry etching process, removing the gate insulating material layer 1050 in the pixel opening area 12, and retaining the gate insulating material layer 1050 in the thin film transistor area 11 to form the gate insulating layer 105. By using the protective layer 104 to protect the gate 1031, the gate insulating material layer 1050 between the pixel electrode 1023 and the common electrode 1091 may be completely removed, thereby improving the storage capacitance, reducing VOP, reducing power consumption, avoiding picture flicker and special picture display abnormalities, ensuring the thickness uniformity of the dielectric layer between the pixel electrode 1023 and the common electrode 1091, and improving the taste of the display panel.

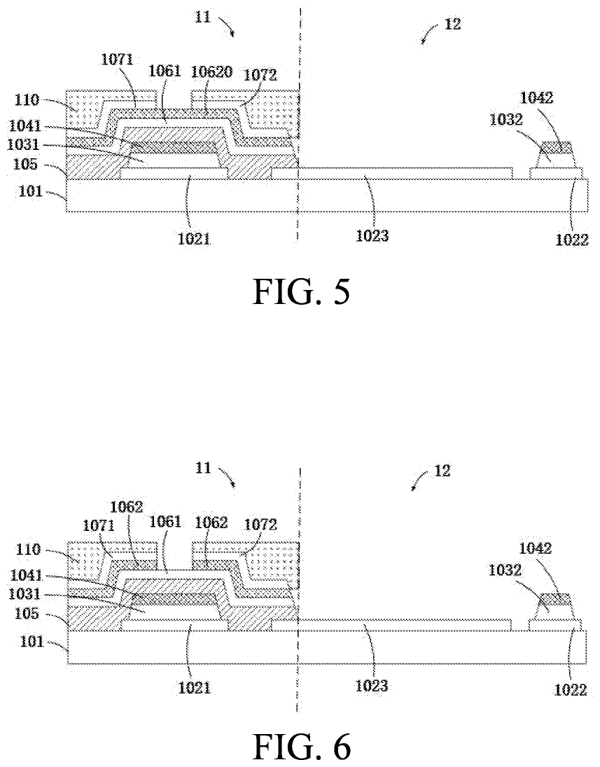

Referring to FIG. 5, the steps S7-S9 further include: etching the photoresist layer 110 to remove the photoresist layer 110 in a middle area to expose the second conductor material layer 1070, etching the second conductor material layer 1070 not covered by the photoresist layer 110 for a second time to form the source 1071 and the drain 1072 spaced apart from each other. The protective material layer cannot be etched by the etching liquid used in the etching the second conductor material layer 1070. The gate 1031 is protected by the protective layer 104 to prevent the gate 1031 from being etched when etching the second conductor material layer 1070, and prevent the gate 1031 from being etched away, so as to avoid the failure of the array substrate 1.

Referring to FIG. 6, the steps S7-S9 further include: etching the ohmic contact unit material layer 10620 for the second time by using a mask to form two ohmic contact units 1062.

As shown in FIG. 1, the present disclosure further provides a display panel 100. The display panel 100 includes the array substrate 1, a color film substrate 2, a liquid crystal layer (not shown) disposed between the array substrate 1 and the color film substrate 2, and supporting columns between the array substrate 1 and the color film substrate 2.

The structure of the array substrate 1 is the same as the structure of the array substrate in the above-mentioned embodiments. Please refer to the descriptions in the above-mentioned embodiments, which will not be described herein.

The present disclosure has been described in detail with respect to an array substrate, a method of manufacturing thereof, and a display panel according to an embodiment of the present disclosure. The principles and implementations of the present disclosure are described in detail here with specific examples. The above description of the embodiments is merely intended to help understand the method and core ideas of the present disclosure. At the same time, a person skilled in the art may make changes in the specific embodiments and disclosure scope according to the idea of the present disclosure. In conclusion, the content of the present specification should not be construed as a limitation to the present disclosure.

What is claimed is:

1. An array substrate, comprising a thin film transistor area and a pixel opening area, and further comprising:
a substrate;
a first conductor layer, disposed on the substrate and comprising a gate in the thin film transistor area;
a protective layer, disposed on the first conductor layer and comprising a gate protecting unit on the gate;
a gate insulating layer, disposed on the gate protecting unit;
an active layer, disposed on the gate insulating layer and in the thin film transistor area; and
a second conductor layer, disposed on a side of the active layer away from the substrate and comprising a source and a drain at intervals in the thin film transistor area.

2. The array substrate according to claim 1, wherein the first conductor layer comprises a first sub conductor layer disposed on the substrate and a second sub conductor layer disposed on the first sub conductor layer, and the gate is disposed in the second sub conductor layer;
the array substrate further comprises a pixel electrode and a common electrode disposed in the pixel opening area, and the first sub conductor layer serves as one of the pixel electrode and the common electrode.

3. The array substrate according to claim 2, further comprising:
a passivation layer, disposed on a side of the second conductor layer away from the substrate; and
a third conductor layer, disposed on the passivation layer and comprising another one of the pixel electrode and the common electrode.

4. The array substrate according to claim 3, wherein the third conductor layer further comprises a drain connecting part, and the passivation layer is provided with a drain contact hole exposing the first sub conductor layer; the drain connecting part connects the drain with the first sub conductor layer through the drain contact hole.

5. The array substrate according to claim 2, wherein the first sub conductor layer comprises a first conductive unit, a second conductive unit, and the pixel electrode at intervals; the pixel electrode is disposed between the first conductive unit and the second conductive unit; the first conductive unit is located in the thin film transistor area, and the second conductive unit is located in the pixel opening area.

6. The array substrate according to claim 5, wherein the second sub conductor layer further comprises a common wiring spaced apart from the gate which is disposed on the first conductive unit, and the common wiring is disposed on the second conductive unit.

7. The array substrate according to claim 6, wherein the protective layer further comprises a common wiring protecting unit disposed on the common wiring.

8. The array substrate according to claim 1, wherein an orthographic projection of the gate insulating layer on the substrate is located outside an orthographic projection of the pixel opening area on the substrate.

9. A method of manufacturing an array substrate, comprising:
forming a first sub conductor material layer on a substrate;
patterning the first sub conductor material layer to form a first conductor layer comprising a gate in a thin film transistor area of the array substrate;
forming a protective material layer on the first conductor layer, and patterning the protective material layer to form a protective layer comprising a gate protecting unit disposed on the gate;
forming a gate insulating material layer on the protective layer;
forming a semiconductor layer on the gate insulating material layer;
forming a second conductor material layer on a side of the semiconductor layer away from the substrate;
forming a photoresist layer on the second conductor material layer;
patterning the second conductor material layer and the semiconductor layer with the photoresist layer as a mask to form an active layer in the thin film transistor area;
removing the gate insulating material layer not covered by the active layer to form a gate insulating layer, and removing a part of the photoresist layer to expose the second conductor material layer; and
etching the second conductor material layer not covered by the photoresist layer to form a second conductor layer comprising a source and a drain at intervals.

10. The method according to claim 9, wherein the protective material layer is not etched by an etching solution used in the etching the second conductor material layer not covered by the photoresist layer.

11. The method according to claim 9, wherein the forming the first sub conductor material layer on the substrate, and patterning the first sub conductor material layer to form the first conductor layer comprising the gate in the thin film transistor area of the array substrate, and the forming the protective material layer on the first conductor layer and patterning the protective material layer to form the protective layer comprising the gate protecting unit on the gate comprise:
forming a first sub conductor material layer on the substrate;
forming a second sub conductor material layer on the first sub conductor material layer;
forming the protective material layer on the second sub conductor material layer; and
patterning the protective material layer, the second sub conductor material layer, and the first sub conductor material layer to form the protective layer, a second sub conductor layer, and a first sub conductor layer, wherein the first sub conductor layer serves as one of the pixel electrode and the common electrode, the second sub conductor layer comprises the gate and the common wiring spaced apart from the gate, and the protective layer further comprises a gate protecting unit disposed on the gate and a common wiring protecting unit disposed on the common wiring.

12. The method according to claim 11, further comprising:
forming a passivation layer on a side of the second conductor layer away from the substrate, and patterning the passivation layer to form a source contact hole exposing the first sub conductor layer; and
forming a third conductor layer on the passivation layer, and patterning the third conductor layer to form another one of the pixel electrode and the common electrode and a drain connecting part connecting the drain to the first sub conductor layer.

13. A display panel comprising an array substrate, wherein the array substrate comprises a thin film transistor area and a pixel opening area, and further comprises:
a substrate;
a first conductor layer, disposed on the substrate and comprising a gate in the thin film transistor area;
a protective layer, disposed on the first conductor layer and comprising a gate protecting unit on the gate;
a gate insulating layer, disposed on the gate protecting unit;
an active layer, disposed on the gate insulating layer and in the thin film transistor area; and
a second conductor layer, disposed on a side of the active layer away from the substrate and comprising a source and a drain at intervals in the thin film transistor area.

14. The display panel according to claim 13, wherein the first conductor layer comprises a first sub conductor layer disposed on the substrate and a second sub conductor layer disposed on the first sub conductor layer, and the gate is disposed in the second sub conductor layer;
the array substrate further comprises a pixel electrode and a common electrode disposed in the pixel opening area, and the first sub conductor layer serves as one of the pixel electrode and the common electrode.

15. The display panel according to claim 13, wherein the array substrate further comprises:
a passivation layer, disposed on a side of the second conductor layer away from the substrate; and
a third conductor layer, disposed on the passivation layer and comprising another one of the pixel electrode and the common electrode.

16. The display panel according to claim 15, wherein the third conductor layer further comprises a drain connecting part, and the passivation layer is provided with a drain contact hole exposing the first sub conductor layer; the drain connecting part electrically connects the drain with the first sub conductor layer through the drain contact hole.

17. The display panel according to claim 14, wherein the first sub conductor layer comprises a first conductive unit, a second conductive unit, and the pixel electrode at intervals; the pixel electrode is disposed between the first conductive unit and the second conductive unit, the first conductive unit is located in the thin film transistor area, and the second conductive unit is located in the pixel opening area.

18. The display panel according to claim 17, wherein the second sub conductor layer further comprises a common wiring spaced apart from the gate, which is located on the first conductive unit, and the common wiring is located on the second conductive unit.

19. The display panel according to claim 18, wherein the protective layer further comprises a common wiring protecting unit disposed on the common wiring.

20. The display panel according to claim 13, wherein an orthographic projection of the gate insulating layer on the substrate is located outside an orthographic projection of the pixel opening area on the substrate.
